(19) United States
(12) Patent Application Publication
(10) Pub. No.: US 2023/0274987 A1
(43) Pub. Date: Aug. 31, 2023

(54) MACHINE LEARNING & INTEGRATED METROLOGY FOR RUN-TO-RUN OPTIMIZATION OF CHIP-TO-WAFER ALIGNMENT ACCURACY

(71) Applicant: Applied Materials, Inc., Santa Clara, CA (US)

(72) Inventors: Ruiping WANG, San Jose, CA (US); Shijing WANG, El Dorado Hills, CA (US); Selim NAHAS, Santa Clara, CA (US); Ying WANG, Singapore (SG); Guan Huei SEE, Singapore (SG)

(21) Appl. No.: 17/680,554

(22) Filed: Feb. 25, 2022

(51) Int. Cl. H01L 21/66; H01L 21/67; H01L 21/687; G05B 19/4155

(52) U.S. Cl. CPC H01L 22/22; G05B 19/4155; H01L 21/67121; H01L 21/67259; H01L 21/68707; G05B 2219/43149; G05B 2219/50391

(57) ABSTRACT

Methods, apparatuses and systems in an integrated bonding system for optimizing bonding alignment between dies and a substrates include bonding, using a bonder of the integrated bonding system, a first die to a first substrate using preset alignment settings, transferring, using a transfer arm/robot of the integrated bonding system, the bonded die-substrate combination to an on-board inspection tool of the integrated bonding system, inspecting, at the on-board inspection tool, an alignment of the bond between the die and the substrate of the bonded die-substrate combination to determine a misalignment measure representing a misalignment of the bond between the die and the substrate of the bonded die-substrate combination, determining from the misalignment measurement, using a machine learning process, a correction measurement to be communicated to the bonder, and bonding, in the bonder, a different die to a different substrate using the determined machine-learning based correction measurement.

### FIELD

Embodiments of the disclosure generally relate to methods, apparatuses and systems for processing substrates. More particularly, embodiments of the disclosure relate to methods, apparatus and systems for improving chip-to-wafer bonding alignment accuracy.

### BACKGROUND

Accurate chip-to-wafer (C2W) alignment is crucial to ensure electrical connectivity. Currently, alignment optimization typically relies on post-bonding misalignment measurement on a stand-alone tool and manual input of a compensating offset into bonder. This process is slow, prone to human error, and limited in optimization rounds. Further, it is usually done only after part change to qualify the bonder alignment performance, but not performed on a timely run-to-run (R2R) basis.

### SUMMARY

A method in an integrated bonding system for optimizing bonding alignment between dies and a substrates includes bonding, using a bonder of the integrated bonding system, a first die to a first substrate using preset alignment settings, transferring, using a transfer arm/robot of the integrated bonding system, the bonded die-substrate combination to an on-board inspection tool of the integrated bonding system, inspecting, at the on-board inspection tool, an alignment of the bond between the die and the substrate of the bonded die-substrate combination to determine a misalignment measure representing a misalignment of the bond between the die and the substrate of the bonded die-substrate combination, determining from the misalignment measurement, using a machine learning process, a correction measurement to be communicated to the bonder, and bonding, in the bonder, a different die to a different substrate using the determined machine-learning based correction measurement.

In some embodiments the method can further include comparing the determined misalignment measure to a threshold to determine whether a determined misalignment of the bond between the die and the substrate of the bonded die-substrate combination is within an acceptable tolerance and if the determined misalignment is determined to not be within the acceptable tolerance, the correction measurement is determined and if the determined misalignment is determined to be within an acceptable tolerance and the determined misalignment is determined to be getting worse, the correction measurement can also be determined. A different die can then be bonded to a different substrate using the determined machine-learning based correction measurement.

An apparatus in an integrated bonding system for optimizing bonding alignment between a die and a substrate includes a processor and a memory coupled to the processor, the memory having stored therein at least one of programs or instructions. The programs or instructions when executed by the processor configure the apparatus to cause a bonder of the integrated bonding system to bond a first die to a first substrate using preset alignment settings, cause a transfer arm/robot of the integrated bonding system to transfer the bonded die-substrate combination to an on-board inspection tool of the integrated bonding system, cause the on-board inspection tool to inspect an alignment of the bond between the die and the substrate of the bonded die-substrate combination to determine a misalignment measure representing a misalignment of the bond between the die and the substrate of the bonded die-substrate combination, determine from the misalignment measurement, using a machine learning process, a correction measurement to be communicated to the bonder, and cause the bonder to bond a different die to a different substrate using the determined machine-learning based correction measurement.

In some embodiments the apparatus further compares the determined misalignment measure to a threshold to determine whether a determined misalignment of the bond between the die and the substrate of the bonded die-substrate combination is within an acceptable tolerance and if the determined misalignment is determined to not be within the acceptable tolerance, the correction measurement is determined. If the determined misalignment is determined to be within an acceptable tolerance and the determined misalignment is determined to be getting worse, a machine-learning based correction measurement can be determined and the bonder can bond a different die to a different substrate using the determined machine-learning based correction measurement.

An integrated bonding system for optimizing bonding alignment between a die and a substrate includes a bonder bonding a first die to a first substrate using preset alignment settings, a transfer arm/robot transferring the bonded die-substrate combination to an on-board inspection tool of the integrated bonding system, and an on-board inspection tool inspecting an alignment of the bond between the die and the substrate of the bonded die-substrate combination to determine a misalignment measure representing a misalignment of the bond between the die and the substrate of the bonded die-substrate combination and determining from the misalignment measurement, using a machine learning process, a correction measurement to be communicated to the bonder, in which the bonder bonds a different die to a different substrate using the determined machine-learning based correction measurement.

In some embodiments, the on-board inspection tool further compares the determined misalignment measure to a threshold to determine whether a determined misalignment of the bond between the die and the substrate of the bonded die-substrate combination is within an acceptable tolerance and if the determined misalignment is determined to not be within the acceptable tolerance, the correction measurement is determined. If the determined misalignment is determined to be within an acceptable tolerance and the determined misalignment is determined to be getting worse, a machine-learning based correction measurement can be determined and the bonder can bond a different die to a different substrate using the determined machine-learning based correction measurement.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a functional flow diagram of a typical chip-to-wafer (C2W) bonding process.

FIG. 2 depicts a high-level block diagram of an integrated bonding system 100 in accordance with an embodiment of the present principles.

FIG. 3 depicts a flow diagram of a method in an integrated bonding system of the present principles, for bonding dies and a substrate(s)/wafer(s) including a machine learning-based alignment correction in accordance with an embodiment of the present principles.

FIG. 4 depicts a functional diagram of an implementation of the method of FIG. 3 for bonding dies and a substrate(s)/wafer(s) including a machine learning-based alignment correction in accordance with an embodiment of the present principles, in a single die-type on substrate scenario in which misalignments are detected.

FIG. 5 depicts a flow diagram of an alternate method in an integrated bonding system of the present principles for bonding dies and a substrate(s)/wafer(s) including a machine learning-based alignment correction and including a threshold comparison procedure in accordance with an embodiment of the present principles.

FIG. 6A depicts a flow diagram of a first portion of an alternate method in an integrated bonding system of the present principles for a multi-die on substrate bonding process including a machine learning-based alignment correction in accordance with an embodiment of the present principles.

FIG. 6B depicts a flow diagram of a second portion of an alternate method in an integrated bonding system of the present principles for a multi-die on substrate bonding process including a machine learning-based alignment correction in accordance with an embodiment of the present principles.

FIG. 7 depicts a functional diagram of an implementation of the method of FIG. 6 for bonding dies and a substrate(s)/wafer(s) including a machine learning-based alignment correction in accordance with an embodiment of the present principles, in a multi-die type on substrate scenario in which misalignments are detected.

FIG. 8 depicts a high-level block diagram of a controller/computing device suitable for use with embodiments of an integrated bonding system in accordance with the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods, apparatus and systems for improving chip-to-wafer alignment accuracy are provided herein. For example, methods, apparatus and systems for improving chip-to-wafer alignment accuracy can comprise a bonder having an onboard inspection tool to enable inline measurement of any misalignment between dies and substrate(s). The measurements from the onboard inspection tool can be communicated to a machine learning process/database which provides feedback to the bonder to correct for any measured misalignment between a die(s) and a substrate(s) based on the feedback. In some embodiments, the measurements from the onboard inspection tool can be continually made or, in addition or alternatively, the measurements from the onboard inspection tool can be made at predetermined intervals or dynamically determined intervals.

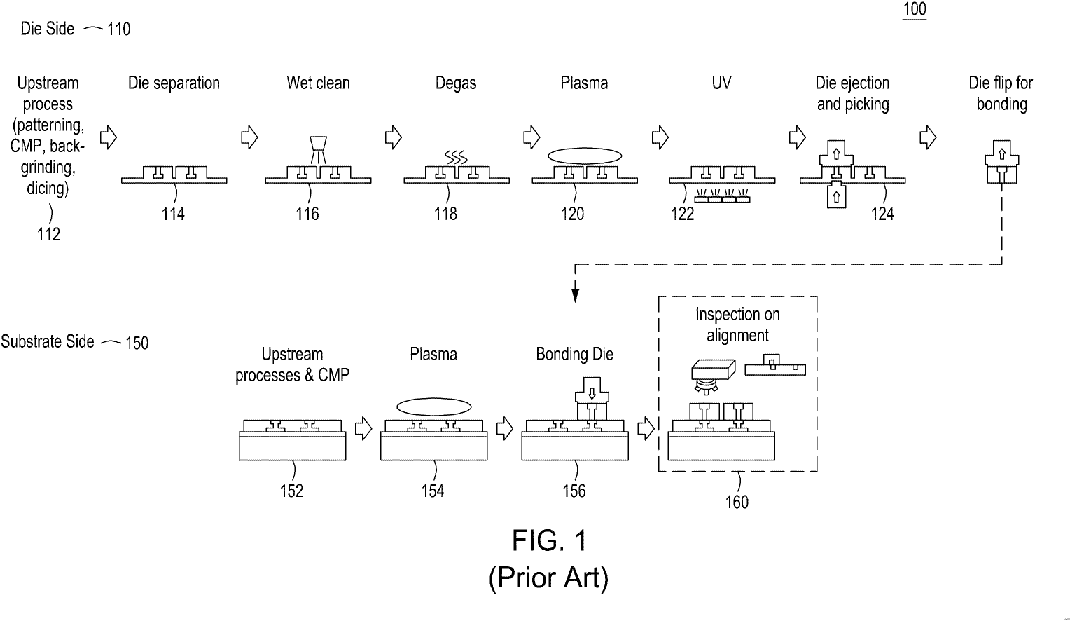

FIG. 1 depicts a functional flow diagram 100 of a typical chip-to-wafer (C2W) bonding process. In FIG. 1, the flow diagram 100 is divided into a die side 110 and a substrate side 150. The die side 110 of FIG. 1 illustratively includes upstream processes 112 which can include patterning, chemical mechanical polishing/planarization (CMP), back-grinding, dicing, and the like. The die side 110 of FIG. 1 further includes a die separation process 114, a wet-clean process 116, a degas process 118, a plasma process 120, a UV process 122, a die ejection and picking process 124, and a die flip for bonding process 126.

In the flow diagram 100 of FIG. 1, the substrate of the substrate side 150 can comprise a wafer with or without a Si- or glass-supported Si wafer, depending on the process flow and use cases. In FIG. 1, the substrate side 150 illustratively includes upstream processes 152 which can include a CMP process. The substrate side 150 of FIG. 1 further includes a plasma process 154, and a bonding die process/tool 156 to create a bonded wafer/die. In some embodiments of the present principles, the substrate side 150 can further include an optional wet clean process (not shown), and an optional degas process (not shown). As depicted in FIG. 1, after the bonding die process 156, the bonded wafer/die is transported to a separate post-bonding mis-alignment measurement process on a stand-alone misalignment measurement tool 160. Any measured misalignment between the wafer and the die measured by the stand-alone misalignment measurement tool 160 can be manual input as a compensating offset to the bonding die process/tool 156 to attempt to correct the measured misalignment. It should be noted that the illustrated processes depicted in FIG. 1 are not intended to be a complete listing or order of processes that can be included in a typical chip-to-wafer (C2W) bonding process, which can include more or less processes in a same or different order.

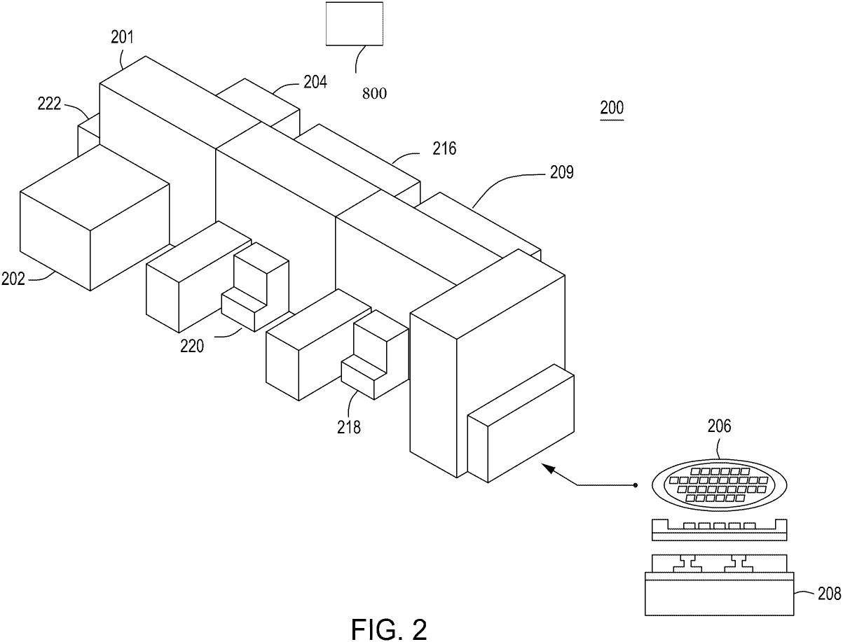

FIG. 2 depicts a high-level block diagram of an integrated bonding system 100 in accordance with an embodiment of the present principles. The integrated bonding system 100 of FIG. 2 illustratively comprises a transfer arm/robot (not shown) in a main body 201, an integrated bonder 202 and an onboard misalignment measurement tool (illustratively an onboard metrology tool) 204. As depicted in FIG. 2, at least one die (illustratively a plurality of singulated dies) 206 and at least one substrate/wafer 208 (illustratively a single substrate/wafer having an adhesive organic tape) are input into the integrated bonding system 100 of FIG. 2. The dies 206 are bonded onto the substrate/wafer 208 in the bonder 202 and then the alignment between the die(s) 206 and the substrate/wafer 208 is measured in the onboard metrology tool 204 to determine any misalignment between the die(s) 206 and the substrate/wafer 208. In some embodiments of the present principles, the die(s) 206 can be bonded to the substrate/wafer 208 one at a time and then the alignment can be measured in accordance with the present principles. In alternate embodiments of the present principles, the die(s) 206 can be bonded to the substrate/wafer 208 more than one at a time and then the alignment can be measured in accordance with the present principles.

As depicted in FIG. 2, the integrated bonding system 200 of FIG. 2 can further include multiple other optional pre-processing chambers including, illustratively, a degas chamber 218 to reduce moisture and other volatile substances from, for example, the adhesive tape, a plasma chamber 220 to clean surface residue, surface activation, and oxide reduction, a UV release chamber 222 to release dies from dicing tape for die picking, a wet clean chamber 216 to clean the substrate/wafer 208, frontside and backside, and to hydrate the substrate/wafer 208, and a factory interface and single or multiple atmospheric mainframes (FI & AMM) integration chamber 209 for better Q-time control and environmental control, such as particle, light and moisture control. The integrated bonding system 200 of FIG. 2 can further include a controller/computing device 800 for performing the methods and processes of the present principles (described in greater detail below). In accordance with embodiments of the present principles, the controller/computing device 800 can be a local device or a remote server (such as a field service server) that is connected to the tool through means such as ethernet. For example, in some embodiments of the present principles, the controller/computing device 800 can be associated with an onboard misalignment measurement tool of the present principles, such as the onboard metrology tool 204 of FIG. 2. More specifically, in some embodiments, the controller/computing device 800 can be in communication with at least one of a bonder and/or an onboard misalignment measurement tool of the present principles, and in some embodiments can be incorporated in at least one of a bonder and/or an onboard misalignment measurement tool of the present principles.

Although specific numbers and types of optional chambers are depicted for the integrated bonding system 200 of FIG. 2, other embodiments of an integrated bonding system of the present principles can include more or less and different types of optional chambers in a same or different order necessary for completing a bonding process.

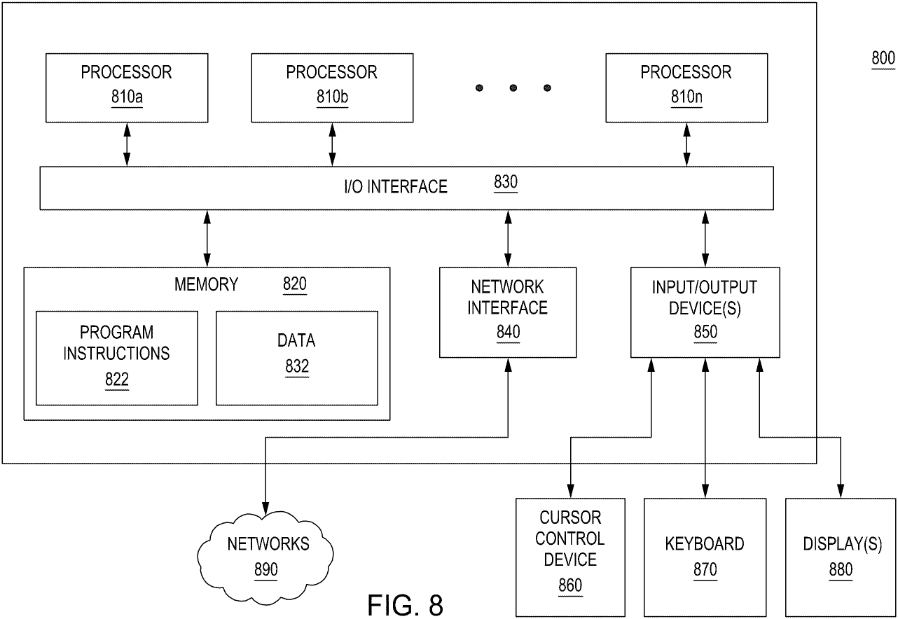

As described above with respect to FIG. 2, the integrated bonding system of the present principles, such as the integrated bonding system 200 of FIG. 2, can include a controller/computing device 800 in the form of, for example, a computing device (described in greater detail below) to perform methods and computing functions of the present principles, such as machine learning processes. In various embodiments described in the present disclosure, the controller/computing device 800 of the present principles is described specifically as a computing device. For example, in some embodiments, the onboard metrology tool 204 can implement a computing device 800 to perform a machine learning process and provide feedback information/data to the bonder 202 of the integrated bonding system 200 of FIG. 2 to correct for any misalignment between a die and a substrate/wafer as measured by the onboard metrology tool 204. In accordance with the present principles, data associated with the computing device (e.g., machine learning data, measurement data) can be stored in a memory of the computing device (described in greater detail with respect to FIG. 8) or any other memory accessible to the computing device.

Embodiments of the present principles provide a method in an integrated bonding system for optimizing bonding alignment between at least one die and at least one substrate which can include at least bonding, using a bonder of the integrated bonding system, a first die to a first substrate using preset alignment settings, transferring, using a transfer arm/robot, the bonded die-substrate combination to an on-board inspection tool of the integrated bonding system, inspecting, at the on-board inspection tool, an alignment of the bond between the die and the substrate of the bonded die-substrate combination to determine a misalignment measure representing a misalignment of the bond between the die and the substrate of the bonded die-substrate combination, determining from the misalignment measurement, using a machine learning process, a correction measurement to be communicated to the bonder, and bonding a different die to a different substrate, in the bonder, using the new machine-learning based correction measurement.

For example, in some embodiments of the present principles, a model is trained using a machine learning process, the model representative of an acceptable (e.g., in tolerance) alignment between a die(s) and a substrate(s). That is, during training, a machine learning process can be exposed to example of acceptably aligned dies and substrates and unacceptably aligned dies and substrates. During the training, the machine learning process can learn to identify bonded dies and substrates that have an in-tolerance alignment, in some embodiments using a loss function. The machine learning process of the present principles can further train on an amount of adjustment to be made to, for example, a bonder to cause the bonder to improve an alignment between bonds between dies and substrates in a more accurate manner (i.e., without over-correcting or under correcting). Subsequently, during bonding of dies and substrates, neural networks can be used in the machine learning process of the present principles to identify bonds between dies and substrates that are acceptable (i.e., within tolerance) and dies that are not acceptable (i.e., out of tolerance).

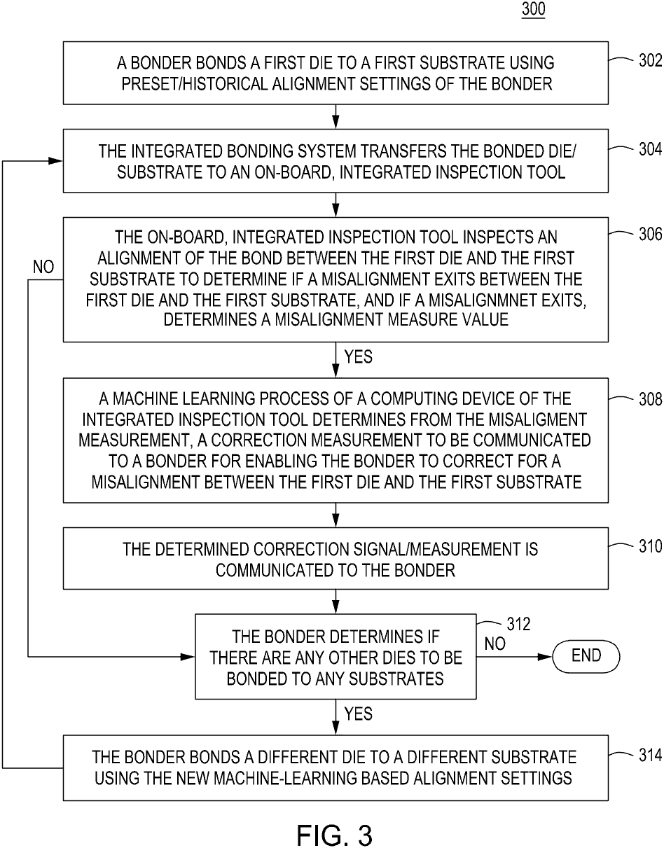

FIG. 3 depicts a flow diagram of a method 300 in an integrated bonding system of the present principles, such as the integrated bonding system 200 of FIG. 2, for bonding dies and a substrate(s)/wafer(s) including a machine learning-based alignment correction in accordance with an embodiment of the present principles. The method 300 begins at 302 during which a bonder, such as the bonder 202 of the integrated bonding system 200 of FIG. 2, bonds a first die to a first substrate with preset/historical alignment settings of the bonder 202. The method 300 can proceed to 304.

At 304, the integrated bonding system of the present principles, such as the integrated bonding system 200 of FIG. 2, transfers the bonded die/substrate, using for example a transfer arm/robot of the integrated bonding system 200 to an on-board, integrated inspection tool of the present principles, such as the onboard metrology tool 204 of the integrated bonding system 200 of FIG. 2. The method 300 can proceed to 306.

At 306, an on-board, integrated inspection tool of the present principles, such as the onboard metrology tool 204, inspects an alignment of the bond between the die and the substrate to determine if a misalignment (or, in some embodiments described below, an out of tolerance misalignment) exists between the die and the substrate to which the die was bonded. If a misalignment exists, the onboard metrology tool 204 measures the misalignment, the bonded first die/first substrate is discarded and the method 300 proceeds to 308. If no misalignment exists, the bonded fist die/first substrate is saved and the method 300 can proceed to 312.

At 308, a machine learning process of a computing device of an integrated inspection tool of the present principles, such as a machine learning process implemented by the computing device 800 of the onboard metrology tool 204, determines from the misalignment measurement, a correction signal/measurement to be communicated to a bonder of the present principles, such as the bonder 202, for enabling the bonder to correct for a misalignment between, for example, the first die and the first substrate. In some embodiments, a machine learning process of the computing device 800 takes into account previous and current measurements to determine a correction signal/measurement to be communicated to the bonder 202 to accurately adjust for any measured misalignment between the first die and the first substrate, for example, without over or under correction for more accuracy. In some embodiments, collected and determined data and machine-leaning data can be sent to an associated machine-learning database to be stored for future use. That is, in accordance with the present principles and as described above, data associated with the computing device (e.g., machine learning data) can be stored in a memory of the computing device (described in greater detail with respect to FIG. 8) or any other memory accessible to the computing device. The method 300 can proceed to 310.

At 310, the determined correction signal/measurement is communicated to a bonder of the present principles, such as the bonder 202 of the integrated bonding system 200 of FIG. 2. The method 300 can proceed to 312.

At 312 an integrated bonding system of the present principles, such as the integrated bonding system 200 of FIG. 2, determines if there are any other dies to be bonded to any substrates. For example, in some embodiments the bonder 202 can determine if there are any other dies to be bonded to any substrates. If it is determined that there are any more dies to be bonded to any substrate, the method can proceed to 314 for at least one of the remaining dies. If it is determined that there are no more dies to be bonded to any substrate, the method 300 can be exited.

At 314, a bonder of the present principles, such as the bonder 202 of the integrated bonding system 200 of FIG. 2, offsets the measured misalignment based on the machine learning determined correction signal/measurement when bonding a second die to a second substrate. That is, in accordance with the present principles, a different die is bonded to a different substrate using the new machine-learning based alignment settings. The method 300 can then return to 304 at which the bonded die/substrate is transferred using, for example a transfer arm/robot, to the onboard metrology tool 204 and the method 300 can proceed as before. The method 300 of FIG. 3 can end when there are no more dies to bond to any more substrates.

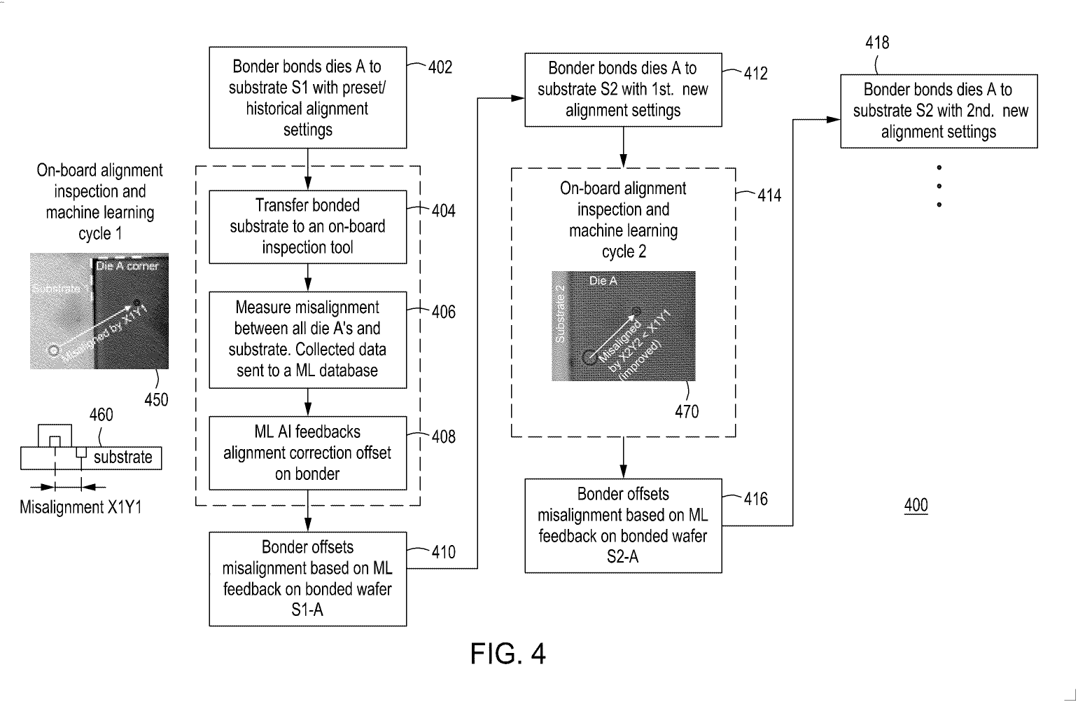

FIG. 4 depicts a functional diagram 400 of an implementation of the method 300 of FIG. 3 for bonding dies and a substrate(s)/wafer(s) including a machine learning-based alignment correction in accordance with an embodiment of the present principles, in a single die-type on substrate scenario in which misalignments are detected.

At 402, a bonder bonds a first die(s) of type A to a first substrate, S1, with preset/historical alignment settings.

At 404, the bonded die/substrate, S1-A, is transferred using, for example a transfer arm/robot of the main body 201 of the integrated bonding system 200 of FIG. 2, to an on-board inspection tool of the present principles, such as the onboard metrology tool 204 of the integrated bonding system 200 of FIG. 2.

At 406, the onboard inspection tool of the present principles measures the misalignment between the bonded die(s), A, and the substrate, S1. A correction signal/measurement is determined to correct for a misalignment between the bonded die and substrate, using, in some embodiments, a machine learning process of the onboard metrology tool 204. Collected and determined data can be sent to an associated machine-learning database to be stored for future use.

In the embodiment of FIG. 4, 450 depicts an illustrative top view of a misalignment between a bonded die, A, and substrate, S1 and 460 depicts an illustrative side view of the same misaligned bonding of the bonded die, A, and substrate, S1 as illustrated by respective copper bonding pads in the die, A, and substrate, S1.

At 408, the correction signal/measurement determined by the onboard metrology tool of the present principles is communicated to the bonder.

In the example of FIG. 4, 404, 406 and 408, together, are considered an on-board alignment inspection & machine learning cycle, in FIG. 4, on-board alignment inspection & machine learning cycle 1.

At 410, the bonder offsets the misalignment of the bond between the die, A, and the substrate, S1, based on the received correction signal/measurement.

At 412, the bonder bonds a different die of the same type, A, to a different substrate, S2, with the new alignment setting based on the received correction signal/measurement.

At 414, a second on-board alignment inspection & machine learning cycle is then performed. That is, in the embodiment of FIG. 4, after the bonder bonds a different die of the same type, A, to a different substrate, S2, with the new alignment setting, the bonded die/substrate S2-A, is transferred using, for example a transfer arm/robot of the main body 201 of the integrated bonding system 200 of FIG. 2, to an on-board inspection tool of the present principles, the onboard inspection tool of the present principles measures the misalignment between the bonded die(s), A, and the substrate, S2 and a second correction signal/measurement is determined, based on the latest misalignment data and historical data, to correct for a misalignment between the bonded die and substrate, using, in some embodiments, a machine learning process, and the correction signal/measurement determined by the onboard metrology tool of the present principles is communicated to the bonder.

In the embodiment of FIG. 4, 470 depicts an illustrative top view of a misalignment between a bonded die, A, and the second substrate, S2, as illustrated by respective copper bonding pads in the die, A, and substrate, S2.

In the example of FIG. 4, at 416, the bonder offsets the misalignment of the bond between the die, A, and the substrate, S2, based on the received, second correction signal/measurement.

At 418, the bonder bonds a different, third die of the same type, A, to a different, third substrate, S3, with the new alignment setting based on the received, second correction signal/measurement.

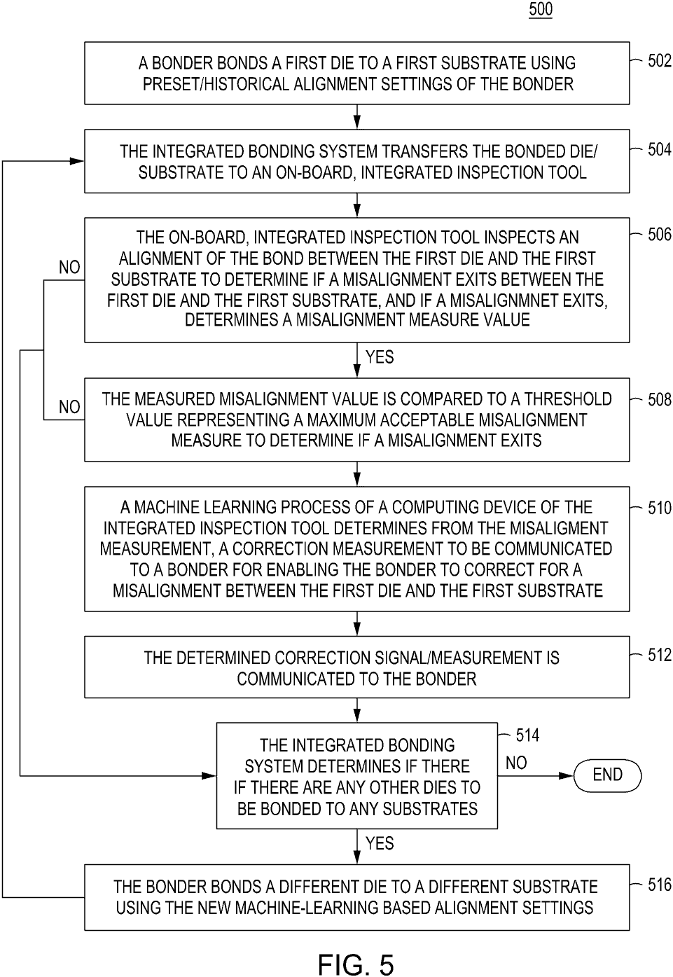

In some embodiments of the present principles, a misalignment measurement can be compared to at least one threshold measurement to determine if a misalignment needs to be corrected in accordance with the present principles or if a misalignment is within an acceptable tolerance for completing an electrical contact between a bonded die and a substrate. For example, FIG. 5 depicts a flow diagram of an alternate method 500 in an integrated bonding system of the present principles, such as the integrated bonding system 200 of FIG. 2, for bonding dies and a substrate(s)/wafer(s) including a machine learning-based alignment correction and including a threshold comparison procedure in accordance with an embodiment of the present principles. The method 500 begins at 502 during which a bonder, such as the bonder 202 of the integrated bonding system 200 of FIG. 2, bonds a first die to a first substrate with preset/historical alignment settings of the bonder 202. The method 500 can proceed to 504.

At 504, the integrated bonding system of the present principles, such as the integrated bonding system 200 of FIG. 2, transfers using, for example a transfer arm/robot of the main body 201 of the integrated bonding system 200 of FIG. 2, the bonded die/substrate to an on-board, integrated inspection tool of the present principles, such as the onboard metrology tool 204 of the integrated bonding system 200 of FIG. 2. The method 500 can proceed to 506.

At 506, an on-board, integrated inspection tool of the present principles, such as the onboard metrology tool 204, inspects an alignment of the bond between the first die and the first substrate to determine if a misalignment exists between the first die and the first substrate to which the first die was bonded. If a misalignment exists, the onboard metrology tool 204 measures the misalignment, the first bonded die/substrate is discarded and the method 500 proceeds to 508. If no misalignment exists, the bonded die/substrate, S1-A is saved and the method 500 can skip to 514.

At 508, the measured misalignment value can be compared to a threshold value representing a maximum acceptable misalignment measure. For example, in some embodiments of the present principles, a threshold value representing a maximum acceptable misalignment measure can be stored in a memory of, for example, a computing device of the present principles, such as the computing device 800 of the onboard metrology tool 204. That is, in accordance with the present principles, data associated with the computing device (e.g., threshold data) can be stored in a memory of the computing device (described in greater detail with respect to FIG. 8) or any other memory accessible to the computing device 800.

At 508, if the misalignment measurement value is greater than the threshold value, the method 500 can proceed to 510. If the misalignment measurement value is less than the threshold value, the method 500 can skip to 514. In some embodiments, however, when the misalignment measurement value is less than the threshold value but misalignment amounts are trending up/worsening based on the stored data of a previous number of runs, the method 500 can take preventive action based on machine-learning/AI-enabled predictive analysis to provide a bonder with an updated corrective offset so that the misalignment measurement value can always be kept at a minimum. More specifically, in some embodiments, when the misalignment measurement value is less than the threshold value but misalignment amounts are trending up/worsening, the method 500 can proceed to 510 instead of skipping to 514.

At 510, a machine learning process of a computing device of an integrated inspection tool of the present principles, such as a machine learning process implemented by the computing device 800 of the onboard metrology tool 204, determines from the misalignment measurement (either out of threshold tolerance or in threshold tolerance but trending up/worsening), a correction signal/measurement to be communicated to the bonder 202, for enabling the bonder to correct for a misalignment between, for example, the first die and the first substrate. In some embodiments, the machine learning process of the computing device 800 takes into account previous and current measurements to determine a correction signal/measurement to be communicated to the bonder 202 to accurately adjust for any measured misalignment between the first die and the first substrate, for example, without over or under correction for more accuracy. The method 500 can proceed to 512.

At 512, the determined correction signal/measurement is communicated to a bonder of the present principles, such as the bonder 202 of the integrated bonding system 200 of FIG. 2. The method 500 can proceed to 514.

At 514, an integrated bonding system of the present principles, such as the integrated bonding system 200 of FIG. 2, determines if there are any other dies to be bonded to any substrates. If it is determined that there are any more dies to be bonded to any substrate, the method can proceed to 516 for at least one of the remaining dies. If it is determined that there are no more dies to be bonded to any substrate, the method 500 can be exited.

At 516, a bonder of the present principles, such as the bonder 202 of the integrated bonding system 200 of FIG. 2, offsets the measured misalignment based on the machine learning determined correction signal/measurement when bonding the remaining selected die to a substrate. That is, in accordance with the present principles, the remaining selected die is bonded to a substrate using the new machine-learning based alignment settings. The method 500 can then return to 504 at which the bonded die/substrate is transferred using, for example a transfer arm/robot of the main body 201 of the integrated bonding system 200 of FIG. 2, to the onboard metrology tool 204 and the method 500 can proceed as before.

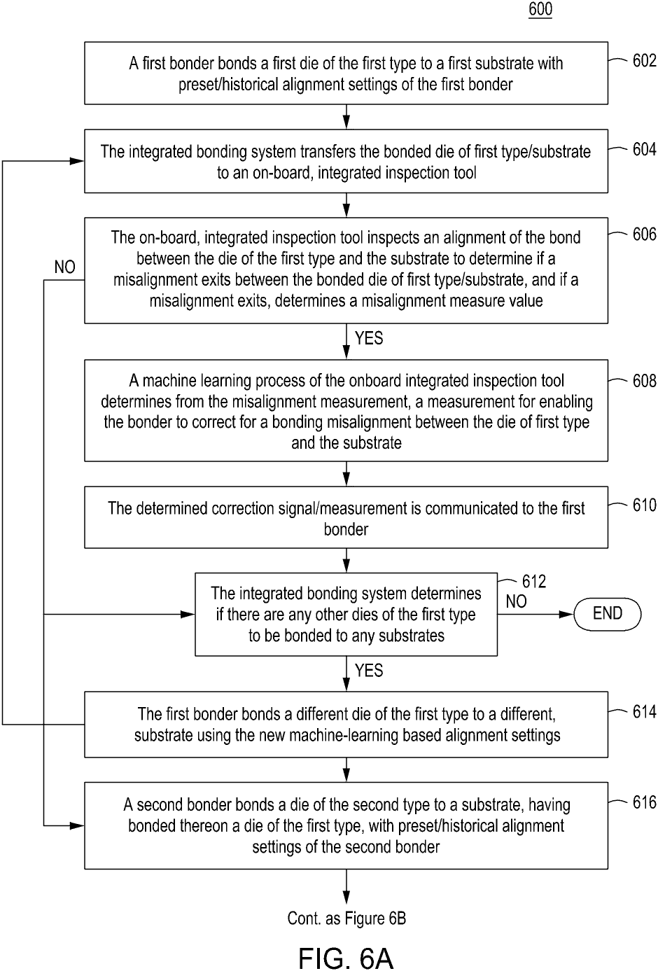

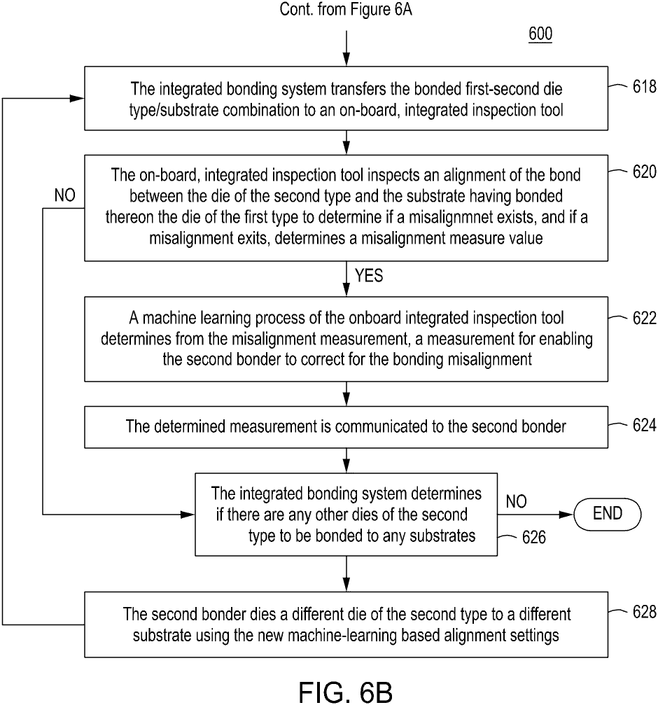

In some embodiments of the present principles, multiple dies can be bonded to a same or different substrates in a same or different bonders of the present principles, such as the bonder 202 of the integrated bonding system 200 of FIG. 2. For example, FIGS. 6A and 6B (collectively referred to herein as FIG. 6) together depict a flow diagram of an alternate method 600 in an integrated bonding system of the present principles, such as the integrated bonding system 200 of FIG. 2, for a multi-die on substrate bonding process including a machine learning-based alignment correction in accordance with an embodiment of the present principles. The embodiment of the method 600 of FIG. 6 is directed to instances in which a first bonder is being implemented to bond dies of a first type to substrates and a second bonder is being implemented to bond dies of a second type to the same or different substrate(s).

The method 600 of FIG. 6 begins at 602 during which the first bonder bonds a first die of the first type to a first substrate with preset/historical alignment settings of the first bonder. The method 600 can proceed to 604.

At 604, the integrated bonding system of the present principles, such as the integrated bonding system 200 of FIG. 2, transfers the bonded first die/first substrate to an on-board, integrated inspection tool of the present principles, such as the onboard metrology tool 204 of the integrated bonding system 200 of FIG. 2. The method 600 can proceed to 606.

At 606, an on-board, integrated inspection tool of the present principles, such as the onboard metrology tool 204, inspects an alignment of the bond between the first die and the first substrate to determine if a misalignment exists between the bonded first die/first substrate. If a misalignment exists, the onboard metrology tool 204 measures the misalignment, the bonded first die/first substrate is discarded and the method 600 proceeds to 608. If no misalignment exists, the bonded first die/first substrate is saved and the method 600 can proceed to 612 and in parallel to 616.

At 608, a machine learning process of a computing device of an integrated inspection tool of the present principles, such as a machine learning process implemented by the computing device 800 of the onboard metrology tool 204, determines from the misalignment measurement, a correction signal/measurement to be communicated to the first bonder for enabling the bonder to correct for a bonding misalignment in the bond between the first die and the first substrate. The method 600 can proceed to 610.

At 610, the determined correction signal/measurement is communicated to the first bonder. The method 600 can proceed to 612.

At 612, an integrated bonding system of the present principles, such as the integrated bonding system 200 of FIG. 2, determines if there are any other dies of the first type to be bonded to any substrates. For example, in some embodiments, the first bonder can determine if there are any other dies of the first type to be bonded to any substrates. If it is determined that there are any more dies of the first type to be bonded to any substrate, the method can proceed to 614. If it is determined that there are no more dies to be bonded to any substrate, the method 600 can be exited.

At 614, the first bonder offsets the measured bonding misalignment based on the machine learning determined correction signal/measurement when bonding a remaining selected die of the first type to a different, selected substrate. For example, in some embodiments, the first bonder bonds a second die of the first type to a second substrate using the correction signal/measurement determined based on the machine learning. The method 600 can then return to 604 at which the bonded second die of the first type and the second substrate is transferred to the onboard metrology tool 204 and the method 600 can proceed as before.

At 616, the second bonder bonds a die of the second type to a substrate, having bonded thereon a die of the first type, with preset/historical alignment settings of the second bonder. That is, in some embodiments, the detection of misaligned dies of the first type on substrates bonded by the first bonder can serve as a gating to bonding of dies of the second type on substrates in the second bonder. The method 600 can proceed to 618.

At 618, the integrated bonding system of the present principles, such as the integrated bonding system 200 of FIG. 2, transfers the bonded first-second die type/substrate combination to an on-board, integrated inspection tool of the present principles, such as the onboard metrology tool 204 of the integrated bonding system 200 of FIG. 2. The method 600 can proceed to 620.

At 620, an on-board, integrated inspection tool of the present principles, such as the onboard metrology tool 204, inspects an alignment of the bond between the die of the second type and the substrate having bonded thereon the die of the first type to determine if a misalignment exists between the bonded die of the second type and the substrate having bonded thereon the die of the first type. If a misalignment exists, the measures the misalignment, the bonded first-second die type/substrate is discarded and the method 600 proceeds to 622. If no misalignment exists, the bonded first-second die substrate is saved and the method 600 can proceed to 626.

At 622, a machine learning process of a computing device of an integrated inspection tool of the present principles, such as a machine learning process implemented by the computing device 800 of the onboard metrology tool 204, determines from the misalignment measurement, a correction signal/measurement to be communicated to the second bonder for enabling the bonder to correct for a bonding misalignment in the bond between the second die and the substrate. The method 600 can proceed to 624.

At 624, the determined correction signal/measurement is communicated to the second bonder. The method 600 can proceed to 626.

At 626, an integrated bonding system of the present principles, such as the integrated bonding system 200 of FIG. 2, determines if there are any other dies of the second type to be bonded to any substrates. For example, in some embodiments, the second bonder can determine if there are any other dies of the second type to be bonded to any substrates. If it is determined that there are any more dies of the second type to be bonded to any substrate, the method can proceed to 628. If it is determined that there are no more dies to be bonded to any substrate, the method 600 can be exited.

At 628, the second bonder offsets the measured bonding misalignment based on the machine learning determined correction signal/measurement when bonding a remaining selected die of the second type to a different, selected substrate. For example, in some embodiments, the second bonder bonds another, different die of the second type to a different substrate using the correction signal/measurement determined based on the machine learning. The method 600 can then return to 618 at which the bonded, different die of the second type and the different substrate is transferred to the onboard metrology tool 204 and the method 600 can proceed to 620 and on, as before.

Embodiments of the present principles for bonding multiple types of dies, such as the method 600 of FIG. 6, can further include a threshold measurement procedure to determine if a misalignment needs to be corrected in accordance with the present principles as depicted in the embodiment of FIG. 5. For example, in an alternate embodiment of the method 600 (referred to herein as method 600A) including a threshold comparison, a misalignment measured at step 606, can be compared in, for example, a step 607A (not shown) to a threshold value representing a maximum acceptable misalignment measure. At step 607B (not shown) if the misalignment measurement value is greater than the threshold value, the method 600A can proceed to 608 of method 600, above. If the misalignment measurement value is less than the threshold value, the method 600A can skip to 612 of method 600, above. In some embodiments, however, when the misalignment measurement value is less than the threshold value but misalignment amounts are trending up/worsening based on the stored data of a previous number of runs, the method 600A can take preventive action based on machine-learning/Al-enabled predictive analysis to provide a bonder with an updated corrective offset so that the misalignment measurement value can always be kept at a minimum. More specifically, in some embodiments, when the misalignment measurement value is less than the threshold value but misalignment amounts are trending up/worsening, the method 600A can proceed to 608 instead of skipping to 612. The method 600A can then proceed as above in method 600.

In addition, although the embodiment of FIG. 6 depicts the bonding of two types of dies, in some embodiments of the present principles, an integrated bonding system of the present principles, such as the integrated bonding system 200 of FIG. 2, can be implemented to bond more than two types of dies in accordance with the present principles.

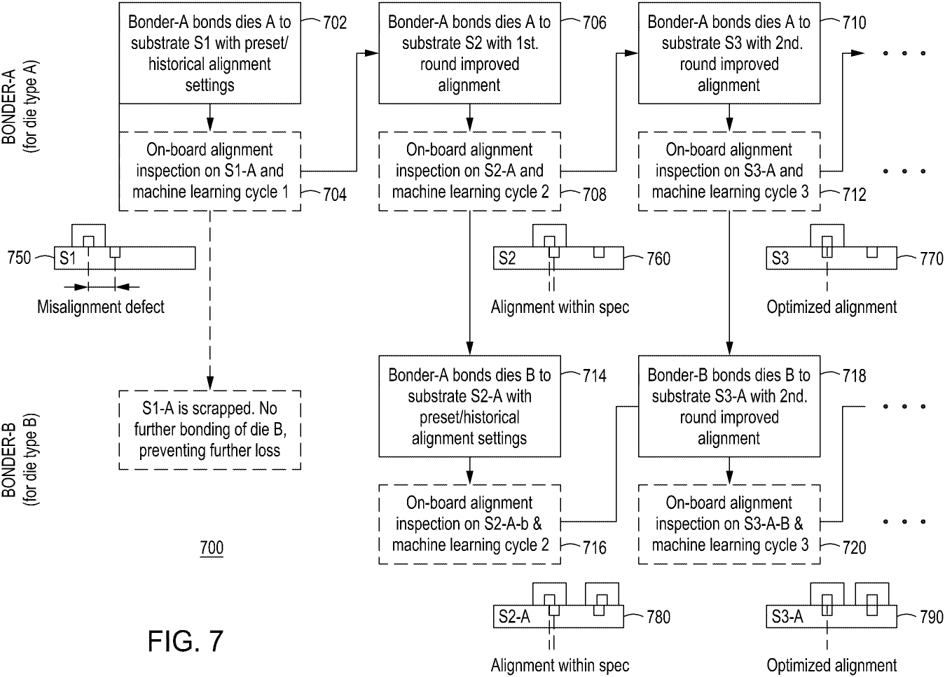

FIG. 7 depicts a functional diagram 700 of an implementation of the method 600 for bonding dies and a substrate(s)/wafer(s) including a machine learning-based alignment correction in accordance with an embodiment of the present principles, in a multi-die type on substrate scenario in which misalignments are detected. In the example of FIG. 7, a first bonder, Bonder A, is being implemented to bond dies of a first type, type A, to substrates, S. Further, in the embodiment of FIG. 7, a second bonder, Bonder B, is being implemented to bond dies of a second type, type B, to the substrates, S.

In the example of FIG. 7, at 702 the first bonder, Bonder A, bonds a die of the first type, A, to a first substrate, S1, with preset/historical alignment settings of the first bonder, Bonder A.

At 704, an on-board, integrated inspection tool of the present principles, such as the onboard metrology tool 204, inspects an alignment of the bond between the die, A, and the first substrate, S1, and determines that a misalignment exists between the die, A, and the first substrate, S1, to which the die was bonded. As such, in the example of FIG. 7, the onboard metrology tool 204 measures the misalignment and the bonded die/substrate, S1-A, is discarded and there is no bonding of a die of the second type, B, in the second bonder, B, preventing further loss of dies and substrates.

In the example of FIG. 7, 750 depicts an illustrative side view of the misaligned bonding of the bonded die, A, and substrate, S1 as illustrated by respective copper bonding pads in the die, A, and substrate, S1.

At 706, Bonder A offsets the measured bonding misalignment based on a machine learning determined correction signal/measurement determined from the measured misalignment and bonds another die of type A to a second substrate S2 using the new machine-learning based alignment settings.

In the example of FIG. 7, at 708, the on-board, integrated inspection tool of the present principles, such as the onboard metrology tool 204, inspects an alignment of the bond between the die, A, and the second substrate, S2, and determines that only a slight misalignment within an acceptable tolerance exists between the die, A, and the first substrate, S1, to which the die was bonded. As such, in the example of FIG. 7, the onboard metrology tool 204 measures the misalignment and the bonded die/substrate, S2-A, is saved.

In the example of FIG. 7, 760 depicts an illustrative side view of the acceptable, in tolerance, bonding of the die of the first type, A, and substrate, S2 as illustrated by respective copper bonding pads in the die, A, and substrate, S2.

In the example of FIG. 7, at 710 Bonder A offsets the measured bonding misalignment based on a machine learning determined correction signal/measurement determined from the measured misalignment of die A on substrate S2 and bonds another die of type A to a third substrate S3 using the new machine-learning based alignment settings to attempt to optimize the alignment of a bond between the die A of the first type and the substrate, S3. For example, in the example of FIG. 7, 770 depicts an illustrative side view of the optimized bonding alignment of the die of the first type, A, and substrate, S3, as illustrated by respective copper bonding pads in the die, A, and the substrate, S3. In the example of FIG. 7, the bonding of the die of the first type, A, and the third substrate S3 is optimal as depicted in 770.

At 712, the process continues and the on-board, integrated inspection tool of the present principles, such as the onboard metrology tool 204, inspects an alignment of the bond between the die, A, and the third substrate, S3 to determine if any misalignment exists between the die of the first type, A, and the third substrate, S3.

In the example of FIG. 7, in parallel to 712 and because the alignment of the bond between the die, A, and the second substrate, S2, was within an acceptable tolerance, at 714 the second Bonder, B, bonds a die of the second type, B, to bonded substrate S2-A with preset/ historical alignment settings.

At 716, the on-board, integrated inspection tool of the present principles, such as the onboard metrology tool 204, inspects an alignment of the bond between the die of the second type, B, and the bonded substrate, S2-A, and determines that only a slight misalignment within an acceptable tolerance exists between the die, B, and the bonded substrate, S2-A, to which the die of the second type, B, was bonded. As such, in the example of FIG. 7, the onboard metrology tool 204 measures the misalignment and the bonded die/substrate, S2-A-B, is saved.

In the example of FIG. 7, 780 depicts an illustrative side view of the acceptable, in tolerance, bonding of the die of the second type, B, and bonded substrate, S2-A as illustrated by respective copper bonding pads in the die, B, and bonded substrate, S2-A.

In the example of FIG. 7, at 718 the second bonder, B, offsets the measured bonding misalignment based on a machine learning determined correction signal/measurement determined from the measured misalignment of die B on bonded substrate S2-A and bonds another die of type B to a bonded substrate, S3-A, using the new machine-learning based alignment settings to attempt to optimize the alignment of a bond between the die B of the second type and the bonded substrate, S3-A. For example, in the example of FIG. 7, 790 depicts an illustrative side view of the optimized bonding alignment of the die of the second type, B, and bonded substrate, S3-A, as illustrated by respective copper bonding pads in the die, B, and the bonded substrate, S3-A. In the example of FIG. 7, the bonding of the die of the second type, B, and the bonded substrate S3-A is optimal as depicted in 790.

At 720, the process continues and the on-board, integrated inspection tool of the present principles, such as the onboard metrology tool 204, inspects an alignment of the bond between the die, B, and the bonded substrate, S3-A to determine if any misalignment exists between the die of the second type, B, and the bonded substrate, S3-A.

Although in the above-described embodiments of the present principles, the embodiments are described as if the bonding of every die on every substrate is inspected in accordance with the present principles for misalignment, the granularity of how often or how many of the bonds are inspected for misalignment is variable in accordance with the present principles. For example, in some embodiments, a granularity of how often or how many of the bonds are inspected for misalignment can be based on at least one of an amount of time available for performing a bonding process and an amount of processing/memory capability of a an integrated bonding system of the present principles. In some embodiments, a granularity of how often or how many of the bonds are inspected for misalignment can be based on a prediction of the machine learning process/artificial intelligence process of the present invention, which can predict, based on a trend of previous and current misalignment measurements, when changing misalignment measurements can become out of tolerance.

In some embodiments, an inspection granularity can be dynamic. For example, in some embodiments, a sampling rate can depend on the maturity and stability of a bonding process. That is, an initial sampling rate can be very high up to 100% (all dies inspected for all bonded substrates). Subsequently, for example, during manufacturing volume ramping, the sampling rate can be 20-80%. Then, during mass production of a very stable process of high proven yield, the sampling rate can be < 10%. The above-described inspection granularities are only exemplary and a frequency of bonding inspection can comprise substantially any frequency in accordance with the present principles.

In accordance with the present principles, die/substrate bonds can have multiple measurement points. For example, in some embodiments, for thin dies (< 200 um thick), measurement can be made at 4 points such as at die corners or even at 5 points (corners + center) to capture potential misalignment caused by die warpage. In other embodiments and for thicker dies (>200 um thick), measurement can be made at 4 points, however it would be possible to reduce measurement to 2 die corners for quick checking during high volume production, if Cu bonding pads are large (>10 um size) and specification/tolerance is not tight.

In some embodiments of the present principles, and as described above, some alignment measurements can include 5 measurements (4 corners and 1 center) sampled per die, and there can be as many as 500 dies per wafer. Therefore, the control system dimension can be as large as 2500 control loops (5 × 500). Since there are no interactions among each control loop, they can be treated as 2500 single-input and single-output control loops, considered by the inventors as Multiple Single-Input and Single-Output (MSISO). The inventors propose herein a MSISO control system which is designed on top of an Exponentially Weighted Moving Average (EWMA) Model. The MSISO control system of the present principles enables a configuration of multiple SISO parameters with same contexts. That is, a MSISO control model design of present principles simplifies configuring multiple SISO parameters by reducing strategy logic of multiple parameters in a single operation. The MSISO control system of the present principles supports a control system with large numbers of inputs and outputs, such as a 1000 input and 1000 output system. A benefit of a MSISO design of the present principles is that all 2500 control loops can be calculated in one shot, instead of looping each control loop one by one (2500 loops). The MSISO method of the present principles improves the calculation time (or reduce computational loading) significantly over currently available methods for processing control loops individually.

In some embodiments of the present principles, alignment measurements taken by an on-board, integrated inspection tool of the present principles, such as the onboard metrology tool 204 of the integrated bonding system 200 of FIG. 2, can be weighted such that measurements that are less trust-worthy (i.e., measurements taken during less-than-ideal conditions) are weighted less than trust-worthy measurements (i.e., measurements taken during better conditions). For example, in some embodiments, current last data points seeming unstable can be weighted 30%, and historical, more reliable measurements can be weighted 70%. The weighting can be a tuning parameter that can be adjusted by a user.

Embodiments of the present principles can further implement a moving horizon technology, which can be applied in each control loop. For example, an adjustment control loop for determining alignment of bonded dies and substrates can be based upon the last 10 data points (or moving window of 10). In the depicted example, the horizon length (e.g. 10) is a tuning parameter that can be adjusted by a user.

FIG. 8 depicts a high-level block diagram of a controller/computing device 800 suitable for use with embodiments of an integrated bonding system in accordance with the present principles such as the integrated bonding system 200 of FIG. 2. In some embodiments, the computing device 800 can be configured to implement methods of the present principles as processor-executable executable program instructions 822 (e.g., program instructions executable by processor(s) 810) in various embodiments.

In the embodiment of FIG. 8, the computing device 800 includes one or more processors 810a-1110n coupled to a system memory 820 via an input/output (I/O) interface 830. The computing device 800 further includes a network interface 840 coupled to I/O interface 830, and one or more input/output devices 850, such as cursor control device 860, keyboard 870, and display(s) 880. In various embodiments, a user interface can be generated and displayed on display 880. In some cases, it is contemplated that embodiments can be implemented using a single instance of computing device 800, while in other embodiments multiple such systems, or multiple nodes making up the computing device 800, can be configured to host different portions or instances of various embodiments. For example, in one embodiment some elements can be implemented via one or more nodes of the computing device 800 that are distinct from those nodes implementing other elements. In another example, multiple nodes may implement the computing device 1100 in a distributed manner.

In different embodiments, the computing device 800 can be any of various types of devices, including, but not limited to, a personal computer system, desktop computer, laptop, notebook, tablet or netbook computer, mainframe computer system, handheld computer, workstation, network computer, a camera, a set top box, a mobile device, a consumer device, video game console, handheld video game device, application server, storage device, a peripheral device such as a switch, modem, router, or in general any type of computing or electronic device.

In various embodiments, the computing device 800 can be a uniprocessor system including one processor 810, or a multiprocessor system including several processors 810 (e.g., two, four, eight, or another suitable number). Processors 810 can be any suitable processor capable of executing instructions. For example, in various embodiments processors 810 may be general-purpose or embedded processors implementing any of a variety of instruction set architectures (ISAs). In multiprocessor systems, each of processors 810 may commonly, but not necessarily, implement the same ISA.

System memory 820 can be configured to store program instructions 822 and/or data 832 accessible by processor 810. In various embodiments, system memory 820 can be implemented using any suitable memory technology, such as static random-access memory (SRAM), synchronous dynamic RAM (SDRAM), nonvolatile/Flash-type memory, or any other type of memory. In the illustrated embodiment, program instructions and data implementing any of the elements of the embodiments described above can be stored within system memory 820. In other embodiments, program instructions and/or data can be received, sent or stored upon different types of computer-accessible media or on similar media separate from system memory 820 or computing device 800.

In one embodiment, I/O interface 830 can be configured to coordinate I/O traffic between processor 810, system memory 820, and any peripheral devices in the device, including network interface 840 or other peripheral interfaces, such as input/output devices 850. In some embodiments, I/O interface 830 can perform any necessary protocol, timing or other data transformations to convert data signals from one component (e.g., system memory 820) into a format suitable for use by another component (e.g., processor 810). In some embodiments, I/O interface 830 can include support for devices attached through various types of peripheral buses, such as a variant of the Peripheral Component Interconnect (PCI) bus standard or the Universal Serial Bus (USB) standard, for example. In some embodiments, the function of I/O interface 830 can be split into two or more separate components, such as a north bridge and a south bridge, for example. Also, in some embodiments some or all of the functionality of I/O interface 830, such as an interface to system memory 820, can be incorporated directly into processor 810.

Network interface 840 can be configured to allow data to be exchanged between the computing device 800 and other devices attached to a network (e.g., network 890), such as one or more external systems or between nodes of the computing device 800. In various embodiments, network 890 can include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, network interface 840 can support communication via wired or wireless general data networks, such as any suitable type of Ethernet network, for example; via digital fiber communications networks; via storage area networks such as Fiber Channel SANs, or via any other suitable type of network and/or protocol.

Input/output devices 850 can, in some embodiments, include one or more display terminals, keyboards, keypads, touchpads, scanning devices, voice or optical recognition devices, or any other devices suitable for entering or accessing data by one or more computer systems. Multiple input/output devices 850 can be present in computer system or can be distributed on various nodes of the computing device 800. In some embodiments, similar input/output devices can be separate from the computing device 800 and can interact with one or more nodes of the computing device 800 through a wired or wireless connection, such as over network interface 840.

Those skilled in the art will appreciate that the computing device 800 is merely illustrative and is not intended to limit the scope of embodiments. In particular, the computer system and devices can include any combination of hardware or software that can perform the indicated functions of various embodiments, including computers, network devices, Internet appliances, PDAs, wireless phones, pagers, and the like. The computing device 800 can also be connected to other devices that are not illustrated, or instead can operate as a stand-alone system. In addition, the functionality provided by the illustrated components can in some embodiments be combined in fewer components or distributed in additional components. Similarly, in some embodiments, the functionality of some of the illustrated components may not be provided and/or other additional functionality can be available.

The computing device 800 can communicate with other computing devices based on various computer communication protocols such a Wi-Fi, Bluetooth.RTM. (and/or other standards for exchanging data over short distances includes protocols using short-wavelength radio transmissions), USB, Ethernet, cellular, an ultrasonic local area communication protocol, etc. The computing device 800 can further include a web browser.

Although the computing device 800 is depicted as a general purpose computer, the computing device 800 is programmed to perform various specialized control functions and is configured to act as a specialized, specific computer in accordance with the present principles, and embodiments can be implemented in hardware, for example, as an application specified integrated circuit (ASIC). As such, the process steps described herein are intended to be broadly interpreted as being equivalently performed by software, hardware, or a combination thereof.

While the foregoing is directed to embodiments of the present disclosure, other and further embodiments of the disclosure may be devised without departing from the basic scope thereof.

In the foregoing description, numerous specific details, examples, and scenarios are set forth in order to provide a more thorough understanding of the present principles. It will be appreciated, however, that embodiments of the principles can be practiced without such specific details. Further, such examples and scenarios are provided for illustration, and are not intended to limit the teachings in any way. Those of ordinary skill in the art, with the included descriptions, should be able to implement appropriate functionality without undue experimentation.

References in the specification to “an embodiment,” etc., indicate that the embodiment described may include a particular feature, structure, or characteristic, but every embodiment may not necessarily include the particular feature, structure, or characteristic. Such phrases are not necessarily referring to the same embodiment. Further, when a particular feature, structure, or characteristic is described in connection with an embodiment, it is believed to be within the knowledge of one skilled in the art to effect such feature, structure, or characteristic in connection with other embodiments whether or not explicitly indicated.

1. A method in an integrated bonding system for optimizing bonding alignment between a die and a substrate, comprising:
bonding, using a bonder of the integrated bonding system, a first die to a first substrate using preset alignment settings;
transferring, using a transfer robot of the integrated bonding system, the bonded die-substrate combination to an on-board inspection tool of the integrated bonding system;
inspecting, at the on-board inspection tool, an alignment of the bond between the die and the substrate of the bonded die-substrate combination to determine a misalignment measure representing a misalignment of the bond between the die and the substrate of the bonded die-substrate combination;
determining from the misalignment measurement, using a machine learning process, a correction measurement to be communicated to the bonder; and
bonding, in the bonder, a different die to a different substrate using the determined machine-learning based correction measurement.

2. The method of claim 1, further comprising:
determining if there are any other dies to be bonded to any substrates.

3. The method of claim 1, further comprising:
comparing the determined misalignment measure to a threshold to determine whether a determined misalignment of the bond between the die and the substrate of the bonded die-substrate combination is within an acceptable tolerance.

4. The method of claim 3, wherein the threshold represents a maximum allowable misalignment of the bond between the die and the substrate of the bonded die-substrate combination.

5. The method of claim 3, wherein if the determined misalignment is determined to not be within the acceptable tolerance, the correction measurement is determined and if the determined misalignment is determined to be within an acceptable tolerance, another die can be bonded to the first substrate.

6. The method of claim 3, wherein if the determined misalignment is determined to be within an acceptable tolerance and the determined misalignment is determined to be getting worse, the correction measurement is determined.

7. The method of claim 3, wherein the another die comprises at least one of a die of a different type and a die bonded to the first substrate using a different bonder of the integrated bonding system.

8. The method of claim 1, further comprising:
after the bonding of the different die to the different substrate using the determined machine-learning based correction measurement, the method of claim 1 returns to the transferring of the bonded die-substrate combination to the on-board inspection tool of the integrated bonding system.

9. An apparatus in an integrated bonding system for optimizing bonding alignment between a die and a substrate, comprising:
a processor; and
a memory coupled to the processor, the memory having stored therein at least one of programs or instructions executable by the processor to configure the apparatus to:
cause a bonder of the integrated bonding system to bond a first die to a first substrate using preset alignment settings;
cause a transfer robot of the integrated bonding system to transfer the bonded die-substrate combination to an on-board inspection tool of the integrated bonding system;
cause the on-board inspection tool to inspect an alignment of the bond between the die and the substrate of the bonded die-substrate combination to determine a misalignment measure representing a misalignment of the bond between the die and the substrate of the bonded die-substrate combination;
determine from the misalignment measurement, using a machine learning process, a correction measurement to be communicated to the bonder; and
cause the bonder to bond a different die to a different substrate using the determined machine-learning based correction measurement.

10. The apparatus of claim 9, wherein the apparatus is further configured to: determine if there are any other dies to be bonded to any substrates.

11. The apparatus of claim 9, wherein the apparatus is further configured to:
compare the determined misalignment measure to a threshold to determine whether a determined misalignment of the bond between the die and the substrate of the bonded die-substrate combination is within an acceptable tolerance.

12. The apparatus of claim 11, wherein the threshold represents a maximum allowable misalignment of the bond between the die and the substrate of the bonded die-substrate combination.

13. The apparatus of claim 11, wherein if the determined misalignment is determined to not be within the acceptable tolerance, the correction measurement is determined and if the determined misalignment is determined to be within an acceptable tolerance, another die can be bonded to the first substrate.

14. The apparatus of claim 13, wherein the another die comprises at least one of a die of a different type and a die bonded to the first substrate using a different bonder of the integrated bonding system.

15. The apparatus of claim 11, wherein if the determined misalignment is determined to be within an acceptable tolerance and the determined misalignment is determined to be getting worse, the correction measurement is determined.

16. The apparatus of claim 9, wherein the apparatus is further configured to:
after the bonding of the different die to the different substrate using the determined machine-learning based correction measurement, again transfer the bonded die-substrate combination to the on-board inspection tool of the integrated bonding system, again cause the on-board inspection tool to inspect an alignment of the bond between the die and the substrate of the bonded die-substrate combination to determine a misalignment measure representing a misalignment of the bond between the die and the substrate of the bonded die-substrate combination, again determine from the misalignment measurement, using a machine learning process, a correction measurement to be communicated to the bonder, and again cause the bonder to bond a different die to a different substrate using the determined machine-learning based correction measurement.

17. An integrated bonding system for optimizing bonding alignment between a die and a substrate, comprising:
a bonder bonding a first die to a first substrate using preset alignment settings;
a transfer robot transferring the bonded die-substrate combination to an on-board inspection tool of the integrated bonding system; and
an on-board inspection tool inspecting an alignment of the bond between the die and the substrate of the bonded die-substrate combination to determine a misalignment measure representing a misalignment of the bond between the die and the substrate of the bonded die-substrate combination and determining from the misalignment measurement, using a machine learning process, a correction measurement to be communicated to the bonder;
wherein the bonder bonds a different die to a different substrate using the determined machine-learning based correction measurement.

18. The system of claim 17, further comprising at least one of a plasma chamber, a UV release chamber, a wet-clean chamber, an integration chamber, and a degas chamber for pre-processing at least one of a die and a substrate.

19. The system of claim 17, further comprising a different bonder for bonding at least one die of a different type than the first die to at least one substrate, including the first substrate.

20. The system of claim 17, wherein the on-board inspection tool further compares the determined misalignment measure to a threshold to determine whether a determined misalignment of the bond between the die and the substrate of the bonded die-substrate combination is within an acceptable tolerance and if the determined misalignment is determined to not be within the acceptable tolerance, the correction measurement is determined and if the determined misalignment is determined to be within an acceptable tolerance and the determined misalignment is determined to be getting worse, the correction measurement is determined and the bonder bonds a different die to a different substrate using the determined machine-learning based correction measurement.
